(19) United States
(12) Patent Application Publication
(10) Pub. No.: US 2025/0316544 A1
(43) Pub. Date: Oct. 9, 2025

(54) SEMICONDUCTOR DEVICE AND POWER CONVERSION APPARATUS

(71) Applicant: Mitsubishi Electric Corporation, Tokyo (JP)

(72) Inventor: Ren KUGA, Tokyo (JP)

(73) Assignee: Mitsubishi Electric Corporation, Tokyo (JP)

(21) Appl. No.: 19/008,581

(22) Filed: Jan. 2, 2025

(30) Foreign Application Priority Data
Apr. 8, 2024 (JP) 2024-061967

(51) Int. Cl. H01L 23/13; H01L 23/00; H01L 23/498; H01L 23/538; H01L 23/64; H01L 25/07; H10D 80/20

(52) U.S. Cl. CPC H01L 23/13; H01L 23/49844; H01L 23/5385; H01L 25/072; H10D 80/20; H01L 23/49894; H01L 23/645; H01L 24/32; H01L 24/48; H01L 24/73; H01L 2224/32225; H01L 2224/48091; H01L 2224/48225; H01L 2224/48464; H01L 2224/73265; H01L 2924/1815

(57) ABSTRACT

A first electrode includes an elongated first contact surface. A second electrode includes the second contact surface provided to face the first contact surface and extend in parallel to the first contact surface. An insulating material is provided between the first electrode and the second electrode. The insulating material extends between the first contact surface and the second contact surface, and has contact with the first contact surface and the second contact surface. The first electrode includes a first corner part located in an end portion of the first contact surface in a width direction. The second electrode includes a second corner part located in an end portion of the second contact surface in a width direction. Each of the first corner part and the second corner part includes any one of a chamfered part and a burr part.

### BACKGROUND OF THE INVENTION

### Field of the Invention

The present disclosure relates to a semiconductor device and a power conversion apparatus.

### Description of the Background Art

Inductance of a current route is reduced in a semiconductor device in which a positive electrode terminal and a negative electrode terminal are disposed in parallel to each other and the same current flows in the positive electrode terminal and the negative electrode terminal in directions opposite to each other (for example, refer to Japanese Patent Application Laid-Open No. 2015-213408).

### SUMMARY

In the semiconductor device in which an insulating material is provided between two electrodes, reduction of inductance of the current route is achieved while a distance between the electrodes are reduced. However, the insulating material is damaged by the electrodes and insulation properties are deteriorated depending on a shape of the electrodes.

An object of the present disclosure is to provide a semiconductor device improving reliability of insulation performance and reducing inductance of a current route.

A semiconductor device according to the present disclosure includes a semiconductor element, a first electrode, a second electrode, and an insulating material. The first electrode includes an elongated first contact surface, and is electrically connected to the semiconductor element. The second electrode includes a second contact surface facing the first contact surface and extending in parallel to the first contact surface. The second electrode is electrically connected to the semiconductor element. The insulating material is provided between the first electrode and the second electrode. The insulating material extends between the first contact surface and the second contact surface, and has contact with the first contact surface and the second contact surface. The first electrode includes a first corner part located in an end portion of the first contact surface in a width direction. The second electrode includes a second corner part located in an end portion of the second contact surface in a width direction. Each of the first corner part and the second corner part includes any one of a chamfered part and a burr part.

Provided is a semiconductor device improving reliability of insulation performance and reducing inductance of a current route.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration of a semiconductor device according to an embodiment 1.

FIG. 2 is a perspective view illustrating a configuration of a first electrode, a second electrode, and an insulating material.

FIG. 3 is a cross-sectional view illustrating a configuration of the first electrode, the second electrode, and the insulating material.

FIG. 4 is a cross-sectional view illustrating a configuration of the insulating material disposed between the first electrode and the second electrode in which a burr part is formed.

FIG. 5 is a cross-sectional view illustrating a configuration of a first electrode, a second electrode, and an insulating material according to an embodiment 2.

FIG. 6 is a cross-sectional view illustrating a configuration of a first electrode, a second electrode, and an insulating material according to an embodiment 3.

FIG. 7 is a cross-sectional view illustrating a configuration of a first electrode, a second electrode, and an insulating material according to an embodiment 4.

### DESCRIPTION OF THE PREFERRED EMBODIMENTS

### Embodiment 1

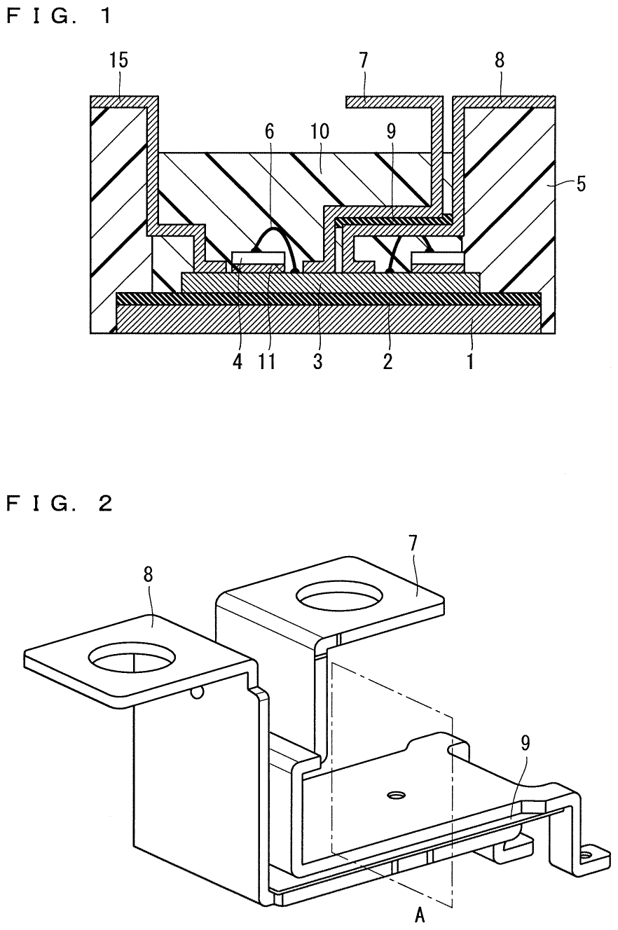

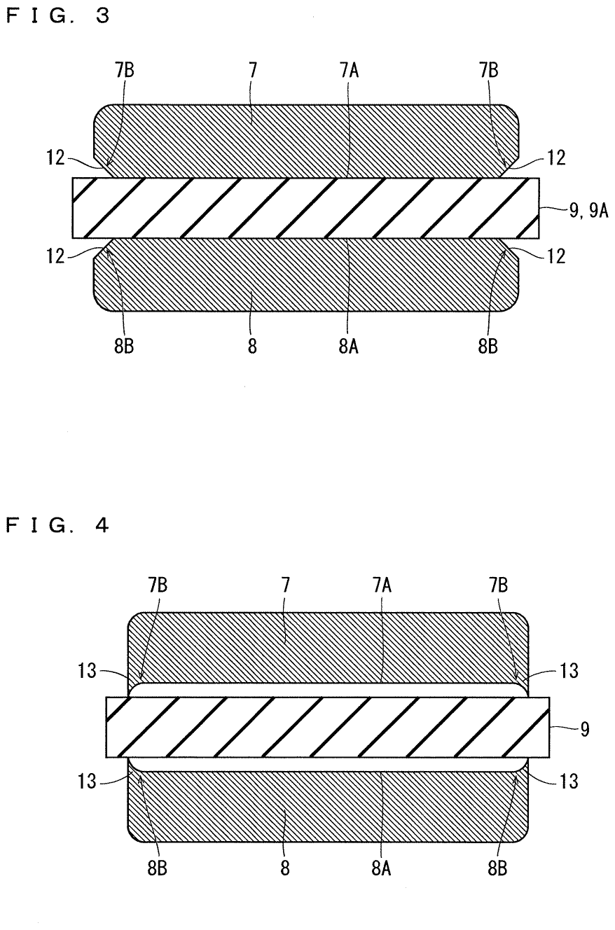

FIG. 1 is a diagram illustrating a configuration of a semiconductor device according to an embodiment 1. The semiconductor device includes a base plate 1, an insulating substrate 2, a metal pattern 3, a semiconductor element 4, a case 5, a metal wire 6, a first electrode 7 and a second electrode 8 as main electrodes, an electrode 15 as the other main electrode, an insulating material 9, and a sealing material 10. FIG. 2 is a perspective view illustrating a configuration of the first electrode 7, the second electrode 8, and the insulating material 9. FIG. 3 is a cross-sectional view illustrating a configuration of the first electrode 7, the second electrode 8, and the insulating material 9. FIG. 3 illustrates a cross section along a planar surface A illustrated in FIG. 2.

The base plate 1 is a plate formed of metal such as copper or aluminum or a plate formed of an AlSiC combined material, for example.

The insulating substrate 2 is provided on the base plate 1. The insulating substrate 2 may be an insulating film formed on the base plate 1. The insulating material 2 is formed of resin or ceramic, for example.

The metal pattern 3 is provided on an upper surface of the insulating substrate 2. The metal pattern 3 is formed of copper, for example.

The semiconductor element 4 is mounted to the metal pattern 3 via a bonding material 11. The bonding material 11 is a conductive material such as solder, for example. The semiconductor element 4 is formed of semiconductor such as Si, for example. The semiconductor element 4 is preferably formed of a wide bandgap semiconductor such as SiC or GaN, for example. The semiconductor element 4 is a power semiconductor element or a control integrated circuit (IC) for controlling the power semiconductor element, for example. The semiconductor element 4 includes an insulated gate bipolar transistor (IGBT), a metal oxide semiconductor field effect transistor (MOSFET), or a Schottky barrier diode, for example. The semiconductor element 4 may include a reverse-conducting IGBT (RC-IGBT) in which an IGBT and a reflux diode are formed in one semiconductor chip.

The case 5 includes a rectangular frame body in a plan view. The case 5 houses the semiconductor element 4, for example, inside the frame body. The case 5 is formed of resin, for example.

The metal wire 6 connects any two of the semiconductor element 4, a terminal, and the metal pattern 3. The terminal includes the first electrode 7 and the second electrode 8.

The first electrode 7 and the second electrode 8 are electrically connected to the semiconductor element 4. The first electrode 7 and the second electrode 8 according to the embodiment 1 are electrically connected to the semiconductor element 4 via the metal pattern 3 or the metal wire 6. The first electrode 7 and the second electrode 8 are main electrodes of the semiconductor device. When the semiconductor element 4 is the IGBT, the first electrode 7 and the second electrode 8 are electrically connected to an emitter and a collector, respectively. The first electrode 7 and the second electrode 8 are plates made up of a planar plate made of metal such as copper processed into a predetermined shape. A part of the first electrode 7 and the second electrode 8 may be embedded into the case 5 and fixed thereto.

The first electrode 7 includes a first contact surface 7A and a first corner part 7B as illustrated in FIG. 3. The first corner part 7B is located in an end portion of the first contact surface 7A in a width direction. The width direction is a direction intersecting with an extension direction of the first electrode 7, and the width direction in the embodiment 1 is a direction perpendicular to the extension direction. The second electrode 8 includes a second contact surface 8A and a second corner part 8B. The second contact surface 8A is provided to face the first contact surface 7A and extends in parallel to the first contact surface 7A. The second corner part 8B is located in an end portion of the second contact surface 8A in a width direction. Each of the first corner part 7B and the second corner part 8B includes a chamfered part 12. The chamfered part 12 is formed by chamfering processing. Each of the first corner part 7B and the second corner part 8B according to the embodiment 1 includes the chamfered part 12. The chamfered part 12 may be a C chamfer or an R chamfer.

The insulating material 9 is provided between the first electrode 7 and the second electrode 8. The insulating material 9 according to the embodiment 1 is an insulating sheet 9A. The insulating sheet 9A extends between the first contact surface 7A and the second contact surface 8A, and has contact with the first contact surface 7A and the second contact surface 8A. In the meanwhile, the insulating sheet 9A does not have contact with the chamfered part 12 of the first corner part 7B and the chamfered part 12 of the second corner part 8B. A thickness of the insulating sheet 9A is equal to or smaller than 0.05 mm, for example. In this manner, the first contact surface 7A of the first electrode 7 and the second contact surface 8A of the second electrode 8 are disposed in parallel and in proximity to each other via the insulating material 9.

The sealing material 10 fills a space inside the frame body of the case 5 as illustrated in FIG. 1. The sealing material 10 seals the semiconductor element 4, a part of the first electrode 7, a part of the second electrode 8, and a part of the electrode 15, for example. The sealing material 10 is silicone resin or epoxy resin, for example.

The first electrode 7 and the second electrode 8 according to the embodiment 1 is formed by press processing. As a result of the press processing, a burr part is formed in the first corner part 7B of the first electrode 7 and the second corner part 8B of the second electrode 8. FIG. 4 is a cross-sectional view illustrating a configuration of the insulating material 9 disposed between the first electrode 7 and the second electrode 8 in which the burr part 13 is formed. When the burr part 13 is formed, the insulating material 9 is easily damaged by the burr part 13. In the semiconductor device according to the embodiment 1, the burr part 13 is removed by chamfering processing. As illustrated in FIG. 3, the chamfered part 12 is formed in the first corner part 7B and the second corner part 8B. As a result, deterioration of insulation performance is reduced, and reliability and performance of the semiconductor device are improved.

In conclusion, the semiconductor device according to the embodiment 1 includes the semiconductor element 4, the first electrode 7, the second electrode 8, and the insulating material 9. The first electrode 7 includes the elongated first contact surface 7A, and is electrically connected to the semiconductor element 4. The second electrode 8 includes the second contact surface 8A provided to face the first contact surface 7A and extend in parallel to the first contact surface 7A. The second electrode 8 is electrically connected to the semiconductor element 4. The insulating material 9 is provided between the first electrode 7 and the second electrode 8. The insulating material 9 extends between the first contact surface 7A and the second contact surface 8A, and has contact with the first contact surface 7A and the second contact surface 8A. The first electrode 7 includes the first corner part 7B located in the end portion of the first contact surface 7A in the width direction. The second electrode 8 includes the second corner part 8B located in the end portion of the second contact surface 8A in the width direction. Each of the first corner part 7B and the second corner part 8B includes the chamfered part 12.

Such a configuration prevents the insulating sheet 9A from being damaged by the burr part 13 occurring in the press processing on the first electrode 7 and the second electrode 8. Insulation defect is reduced, and reliability and performance of the insulation performance of the semiconductor device are improved.

Since the distance from the first electrode 7 to the second electrode 8 is reduced, internal inductance is reduced, and performance of the semiconductor device is improved. When the thickness of the insulating sheet 9A is equal to or smaller than 0.05 mm, inductance is further reduced.

Since the semiconductor element 4 is formed by wide bandgap semiconductor, accuracy of overcurrent protection is improved, and the semiconductor device can also be downsized.

The semiconductor device according to the embodiment 1 can be adopted to a power conversion apparatus. For example, the power conversion apparatus includes at least one semiconductor device described above. Accordingly, the power conversion apparatus is downsized. The power conversion apparatus is an inverter apparatus, a converter apparatus, a servo amplifier, a power source unit, for example.

### Embodiment 2

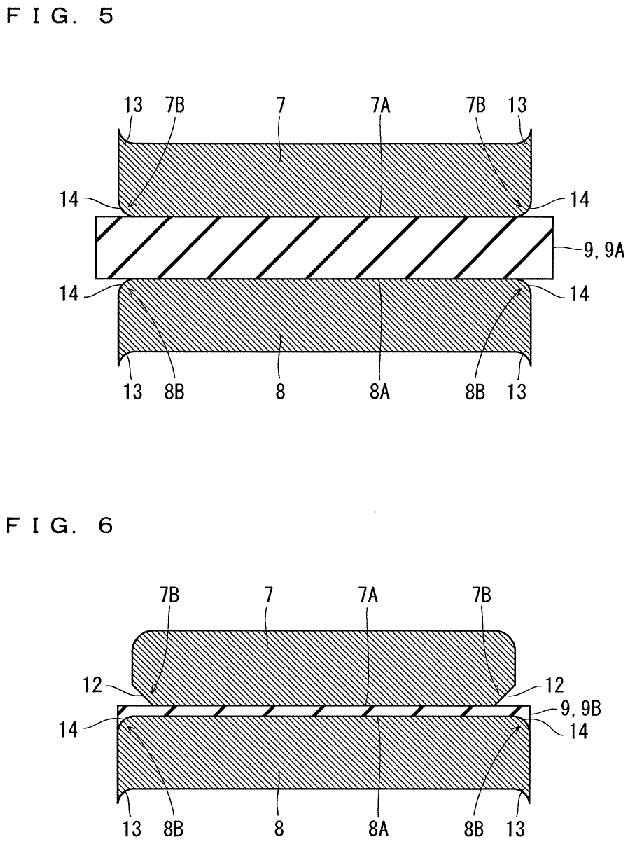

FIG. 5 is a cross-sectional view illustrating a configuration of the first electrode 7, the second electrode 8, and the insulating material 9 according to an embodiment 2. Each of the first corner part 7B and the second corner part 8B includes a burr part 14. In other words, the first contact surface 7A and the second contact surface 8A are formed in a burr surface including the burr part 14. The burr part 14 is formed by press processing.

The insulating material 9 according to the embodiment 2 is the insulating sheet 9A. The insulating sheet 9A has contact with the first contact surface 7A and the second contact surface 8A. In the meanwhile, the insulating sheet 9A does not have contact with the burr part 14 of the first corner part 7B and the burr part 14 of the second corner part 8B.

According to such a configuration, processing for removing the burr part 13 occurring by the press processing is unnecessary. In addition to the effect of the embodiment 1, the number of processes in a process of manufacturing the semiconductor device is reduced, and productivity is improved.

In conclusion of the embodiments 1 and 2, each of the first corner part 7B and the second corner part 8B includes any one of the chamfered part 12 and the burr part 14; thus, reliability of the insulation performance is improved, and inductance of the current route is reduced.

### Embodiment 3

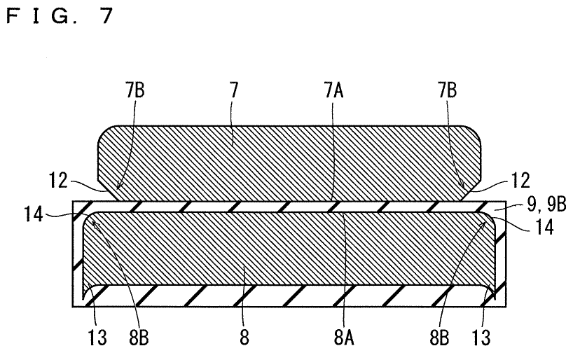

FIG. 6 is a cross-sectional view illustrating a configuration of the first electrode 7, the second electrode 8, and the insulating material 9 according to an embodiment 3. The insulating material 9 is an insulting coating layer 9B covering the second contact surface 8A. A width of the second contact surface 8A is larger than that of the first contact surface 7A. The insulating coating layer 9B has contact with the burr part 14 of the first contact surface 7A, the second contact surface 8A, and the second corner part 8B. In the meanwhile, the insulating coating layer 9B does not have contact with the burr part 14 of the first corner part 7B.

According to such a configuration, a process of inserting the insulating sheet 9A is unnecessary in the process of manufacturing the semiconductor device, and operation efficiency is improved. In addition to the effect of the embodiment 1, productivity in the process of manufacturing the semiconductor device is improved.

Although the illustration is omitted, the chamfered part 12 may be formed in the second corner part 8B of the second electrode 8 in the manner similar to the first corner part 7B of the first electrode 7 (refer to FIG. 3). The insulating coating layer 9B may be provided to have contact with the chamfered part 12 of the second corner part 8B. Also according to such a configuration, an effect similar to that in the embodiment 3 is obtained.

### Embodiment 4

FIG. 7 is a cross-sectional view illustrating a configuration of the first electrode 7, the second electrode 8, and the insulating material 9 according to an embodiment 4. The insulating material 9 is an insulting coating layer 9B covering the second contact surface 8A. The insulating coating layer 9B according to the embodiment 4 is formed in a whole surface of an outer periphery of the second electrode 8.

According to such a configuration, a creeping distance in the second electrode 8 is ensured; thus, reliability of the semiconductor device is improved.

In the present disclosure, each embodiment can be arbitrarily combined, or each embodiment can be appropriately varied or omitted.

The aspects of the present disclosure are collectively described hereinafter as appendixes.

### Appendix 1

A semiconductor device, comprising:
a semiconductor element;
a first electrode including an elongated first contact surface and electrically connected to the semiconductor element;
a second electrode including a second contact surface facing the first contact surface and provided to extend in parallel to the first contact surface, and electrically connected to the semiconductor element; and
an insulating material provided between the first electrode and the second electrode, extending between the first contact surface and the second contact surface, and having contact with the first contact surface and the second contact surface, wherein
the first electrode includes a first corner part located in an end portion of the first contact surface in a width direction,
the second electrode includes a second corner part located in an end portion of the second contact surface in a width direction, and
each of the first corner part and the second corner part includes any one of a chamfered part and a burr part.

### Appendix 2

The semiconductor device according to Appendix 1, comprising:
a base plate; and
an insulating substrate including a metal pattern and provided on the base plate, wherein
the semiconductor element is mounted to the metal pattern of the insulating substrate.

### (Appendix 3)

The semiconductor device according to Appendix 1 or 2, wherein
the insulating material is an insulating sheet, and
a thickness of the insulating sheet is equal to or smaller than 0.05 mm.

### Appendix 4

The semiconductor device according to any one of Appendixes 1 to 3, wherein
the insulating material is an insulating sheet, and
the insulating sheet does not have contact with the first corner part and the second corner part.

### Appendix 5

The semiconductor device according to any one of Appendixes 1 to 3, wherein
the insulating material is an insulating coating layer covering the second contact surface, and
a width of the second contact surface is larger than a width of the first contact surface.

### Appendix 6

The semiconductor device according to Appendix 5, wherein
the insulating coating layer is formed in a whole surface of an outer periphery of
the second electrode.

### Appendix 7

The semiconductor device according to any one of Appendixes 1 to 3, wherein
the insulating material is an insulating coating layer covering the second contact surface, and
the insulating coating layer does not have contact with the first corner part, but has contact with the second corner part.

### Appendix 8

The semiconductor device according to any one of Appendixes 1 to 7, wherein
the semiconductor element is formed of wide bandgap semiconductor.

### Appendix 9

A power conversion apparatus, comprising:
the semiconductor device according to any one of Appendixes 1 to 8.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor element;
a first electrode including an elongated first contact surface and electrically connected to the semiconductor element;
a second electrode including a second contact surface facing the first contact surface and provided to extend in parallel to the first contact surface, and electrically connected to the semiconductor element; and
an insulating material provided between the first electrode and the second electrode, extending between the first contact surface and the second contact surface, and having contact with the first contact surface and the second contact surface, wherein
the first electrode includes a first corner part located in an end portion of the first contact surface in a width direction,
the second electrode includes a second corner part located in an end portion of the second contact surface in a width direction, and
each of the first corner part and the second corner part includes any one of a chamfered part and a burr part.

2. The semiconductor device according to claim 1, comprising:
a base plate; and
an insulating substrate including a metal pattern and provided on the base plate, wherein
the semiconductor element is mounted to the metal pattern of the insulating substrate.

3. The semiconductor device according to claim 1, wherein
the insulating material is an insulating sheet, and
a thickness of the insulating sheet is equal to or smaller than 0.05 mm.

4. The semiconductor device according to claim 1, wherein
the insulating material is an insulating sheet, and
the insulating sheet does not have contact with the first corner part and the second corner part.

5. The semiconductor device according to claim 1, wherein
the insulating material is an insulating coating layer covering the second contact surface, and
a width of the second contact surface is larger than a width of the first contact surface.

6. The semiconductor device according to claim 5, wherein
the insulating coating layer is formed in a whole surface of an outer periphery of the second electrode.

7. The semiconductor device according to claim 1, wherein
the insulating material is an insulating coating layer covering the second contact surface, and
the insulating coating layer does not have contact with the first corner part, but has contact with the second corner part.

8. The semiconductor device according to claim 1, wherein
the semiconductor element is formed of wide bandgap semiconductor.

9. A power conversion apparatus, comprising
the semiconductor device according to claim 1.
